(19) United States
(12) Patent Application Publication
(10) Pub. No.: US 2015/0326177 A1
(43) Pub. Date: Nov. 12, 2015

(54) Integrated Wire Management for Roof-Integrated Solar Panels

(71) Applicant: Integrated Solar Technology, LLC, Larchmont, NY (US)

(72) Inventor: Oliver Koehler, Larchmont, NY (US)

(73) Assignee: Integrated Solar Technology, LLC, Larchmont, NY (US)

(21) Appl. No.: 14/270,572

(22) Filed: May 6, 2014

(51) Int. Cl. H02S 40/34; H01L 31/02

(52) U.S. Cl. CPC H02S 40/34; H01L 31/0201

(57) ABSTRACT

Roof-Integrated solar panels use junction boxes with short cables and connectors at opposite corners. Panel to panel connection is achieved by integrated hooks keeping the cable and connector at either end of the solar panel from touching the roof's decking or battens during installation. Row to row panel connections use simple or specialized jumper cables. The simple jumper cables connect the last solar panel in a row to the next or first solar panel in the next row. “Mini-String” panel group connections use jumper cable. A jumper cable is used to connect groups of roof-integrated panels into DC to DC power optimizers or DC to AC microinverters.

### RELATED PATENT APPLICATION

This application is related to docket no. IS14-002, Ser. No. ______, filed on ______, titled “Advanced Frame Design for Roof-Integrated Solar Panels”, assigned to a common assignee, and which is herein incorporated by reference in its entirety.

### TECHNICAL FIELD

The present document relates to photovoltaic solar panels. In particular, the present document relates to designs of roof-integrated photovoltaic solar panels facilitating simple module-to-module, row-to-row, and panel-to-panel connections.

### BACKGROUND

Current practice in the solar industry in general as well as for roof-integrated solar panels is to use a single junction box with two cables coming out of it where the combined length of the cables exceeds the longer length of the solar panel. FIG. 1a prior art shows a back view of a standard solar panel having a single junction box 10 and two long cables 11 with connectors 12 and 13. Each cable has usually a length of about 1000 mm. FIG. 1b prior art illustrates a standard roof-integrated solar panel with also a single junction box 10 and with two cables 14 and 15 of different length wherein the combined length of both cables still exceeds the longer length of the solar panel. This looks expedient as it minimizes materials and the cables are of sufficient length to enable the solar panel to be connected in either a landscape or portrait orientation. The main disadvantage of this approach is that there is typically excess cable or wire length that must be managed by looping the cable and securing it to the panel through a wire-tie or a wire-clip.

This extra cable management is a small issue for conventional rack-mounted solar panel installations, but is a larger issue for roof-integrated solar panel installations. The reason is that since the roof-integrated panel is attached directly to the roof's decking or battens and successive rows overlap each other, there is limited space to properly stow the cables and once the roof-integrated panels have been secured to the roof it is very difficult to determine if the cables have not been pinched between the roof deck and the solar panel or between separate solar panels. This is very critical since a pinched cable is a potential fire hazard as it can lead to arcing if the cable becomes frayed or damaged over time. This is a major issue, actual damaging field failures have actually occurred for which the likely cause was exactly the issue explained above.

To solve this issue, a different design approach is necessary for the roof-integrated solar panel which includes the solar panel's circuit design, the type of junction box used, and a new installation method for wiring together an array of roof-integrated solar panels

### SUMMARY

A principal object of the present disclosure is to achieve solar panel circuit design which enables use of a junction box with short cables and connectors at opposite corners of the solar panel in a way that the panel's circuit is still protected by a bypass diode.

A further object of the present disclosure is to achieve solar panel circuit design which enables use of a junction box with short cables and connectors at opposite corners of the solar panel when in a landscape orientation in a way that the panel's circuit is still protected by a bypass diode.

A further object of the disclosure is to achieve simple panel to panel connection with no cable management required.

A further object of the disclosure is to make panel-to-panel and row-to-row connections shorter and with less I2R electrical losses.

A further object of the disclosure is to connect groups of roof-integrated panels into DC to DC power optimizers or DC to AC microinverters.

A further object of the disclosure is to enable an easy installation of the solar panels without the risk of pinching cables.

In accordance with the objects of this disclosure a solar panel capable of roof integration with short cables and connectors at opposite ends has been achieved, The solar panel design disclosed comprises: a number of solar cells deployed in one or more rows, wherein the solar cells of each row are interconnected, a positive and a negative junction box located each in an opposite corner on the same side of the solar panel wherein each solar panel has a positive voltage terminal and a negative voltage terminal with short cables and connectors on the same side, wherein a positive junction box is connected to the positive voltage terminal and the negative junction box is connected to the negative voltage terminal. Furthermore the solar panel comprises a bypass diode and a number of busbars located at top and at both sides of the solar panel configured to enable a current flow starting at the positive terminal, ending at the negative terminal wherein the current flows through all solar cells unless the bypass diode diverts incoming current past the solar cells due to shading of a particular solar panel, wherein the deployment of busbars differs between solar panels having an even number of rows of solar cells and solar panels having an odd number of rows of solar cells.

In accordance with the objects of this disclosure a solar panel array capable of roof integration of a number of solar panels with short cables and connectors and junction boxes at a same side at opposite ends has been achieved. The solar panel array disclosed comprises: a number of solar panels each solar panel comprising: a number of solar cells deployed in one or more rows, a positive and a negative junction box located each in an opposite corner on a same side of each solar panel, wherein each solar panel has a positive voltage terminal and a negative voltage terminal with short cables and connectors at the opposite corners on the same side, wherein a positive junction box is connected to the positive voltage terminal and the negative junction box is connected to the negative voltage terminal, a bypass diode; and a number of busbars located at top and at both sides of each solar panel enabling a current flow starting at the positive terminal, ending at the negative terminal wherein the current flows through all solar cells unless said bypass diode diverts incoming current past the solar cells due to shading of a particular solar panel, wherein the deployment of busbars differs between solar panels having an even number of rows of solar cells and solar panels having an odd number of rows of solar cells. The connectors at each end of the short cables provide directly connection from one solar panel to a neighboring solar panel to form a row of solar panels.

In accordance with the objects of this disclosure a method to achieve roof-integrated solar panels with short cables and connectors at opposite ends has been achieved. The method disclosed comprises the steps of: (1) providing solar panels configured for roof integration, wherein each solar panel comprises one or more rows of solar cells, wherein the solar cells of each row are interconnected, and wherein each solar panel includes a positive and a negative junction box, (2) minimizing pinching of cables by enabling using short cables by placing each of the two junction boxes in opposite corners on the same side of each solar panel wherein each solar panel has a positive voltage terminal and a negative voltage terminal connected to the correspondent positive or negative junction box with each terminal having said short cable with a connector at the end, and (3) deploying busbars configured to enable a current flow starting at the positive terminal outlet, ending at the negative terminal outlet, wherein the current flows through all solar cells, wherein a bypass diode diverts incoming current past the solar cells of a particular solar panel in case the cells of the particular solar panel are shaded, wherein the deployment of busbars differs between solar panels having an even number of solar cell rows and solar panels having an odd number of solar cells rows. Furthermore the method comprises the steps of (4) laying the cables into integrated hooks, laying the solar panels down and attaching them to a roof deck or battens wherein the integrated hooks keep cables from getting pinched between the solar panel and roof deck or battens during installation and (5) taking positive or negative connectors of one solar panel out of the hooks and connect them to neighboring positive or negative connectors of an adjacent panel.

### BRIEF DESCRIPTION OF THE FIGURES

The invention is explained below in an exemplary manner with reference to the accompanying drawings, wherein

FIG. 1a prior art shows a back view of a standard solar panel having a single junction box with long cables and with connectors.

FIG. 1b prior art illustrates a standard roof-integrated solar panel with also one single junction box with 2 cables of different length, wherein the combined length of both cables still exceeds the longer length of the solar panel.

FIG. 1c shows a back view of a solar panel circuit design disclosed with two junction boxes located in the corners, where one junction box includes a bypass diode.

FIG. 2a shows a front view of a roof integrated solar panel disclosed with corner J-boxes (not shown in front view) and with an even number of rows, e.g. 2 rows, of solar cells.

FIG. 2b shows a perspective side view of the solar panel having two rows.

FIG. 3a shows a front view of a roof integrated solar panel disclosed with corner J-boxes (not shown in front view) and with an odd number of rows, e.g. 3 rows, of solar cells.

FIG. 3b shows a perspective view of a solar panel having an odd number of rows, namely 3 rows.

FIG. 3c shows a front view of a specialized busbar design which absorbs thermal expansion and contraction of the long horizontal busbar length across the top of the solar panel circuit by e.g. meandering of the busbar.

FIG. 4 illustrates simple panel-to-panel connection of solar panels without cable management required.

FIG. 5 shows a simple row-to-row connection of solar panels following a string inverter concept disclosed.

FIG. 6 illustrates a power optimizer or microinverter “mini-string” concept.

FIG. 7 shows a flowchart of a method to achieve roof-integrated solar panels with short cables and connectors at opposite ends.

### DETAILED DESCRIPTION

Methods and circuits are disclosed for roof integrated solar panels. The solar panels disclosed may be installed either in “landscape mode”, in “portrait mode” or in other orientations.

“Landscape mode” means the longer side of each solar panel is installed approximately parallel to the top and bottom edges of the roof, or other surface, on which the panels are mounted. “Portrait mode” means the shorter side of each solar panel is installed approximately parallel to the top and bottom edges of the mounting surface.

It should be noted that the following disclosed solar panels are applicable to ‘tile’ and ‘shingle’ versions of solar panels. These solar panels integrate with shingle and tile types of roofing materials.

Shingles or especially asphalt shingles are commonly used on many roofs. Concrete, ceramic or other material tiles are more used in hot areas due to better cooling, and durability.

Shingle-based solar panels would be attached to the roof decking over a layer or layers of roof underlayment, while tile-based panels would be typically mounted either directly to the decking over a layer or layers of underlayment or onto standard wooden battens or elevated battens depending on the preference of the builder/roofer or regional code requirements.

It should be noted that the present disclosure is applicable to solar panels in landscape mode, in portrait mode or in other modes/shapes as e.g. potentially in quadratic shape. For example, the solar modules of the disclosure could be used on the side of a building or in the trough of a standing seam metal roof, in portrait mode

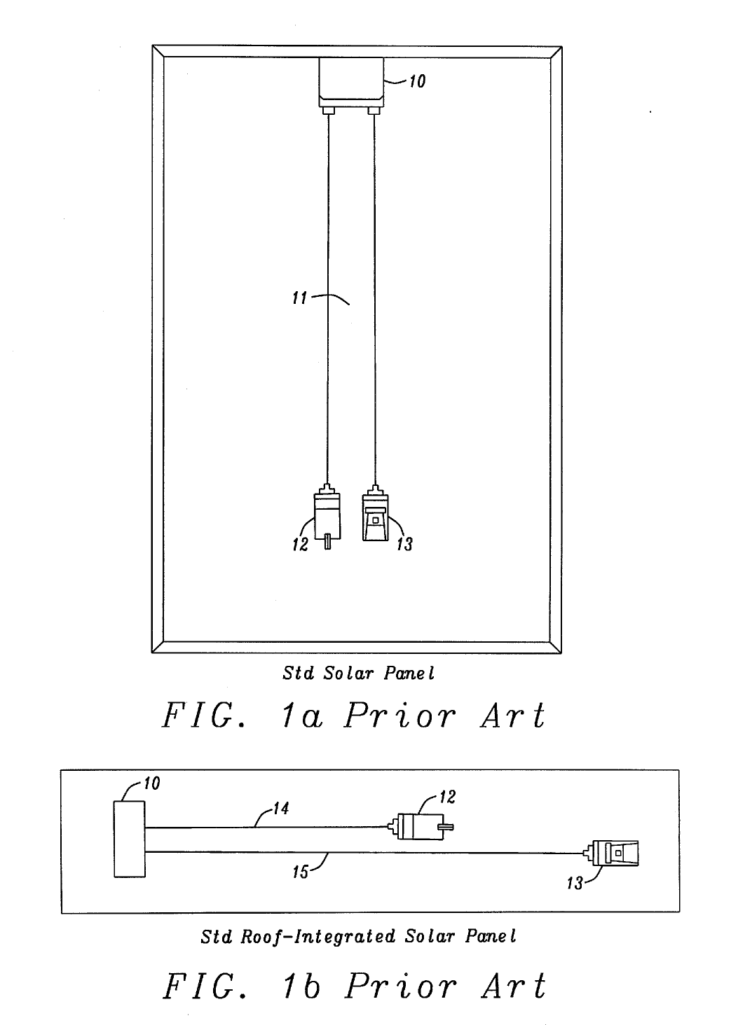

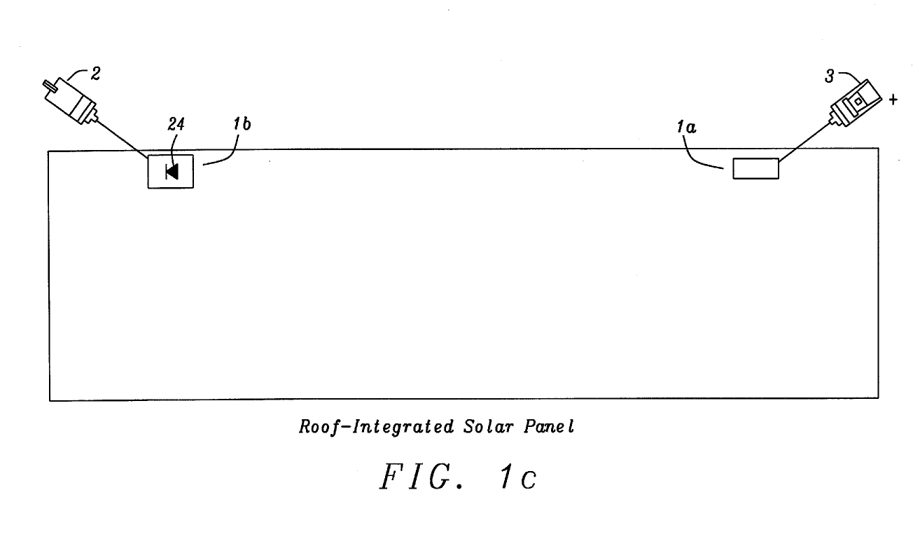

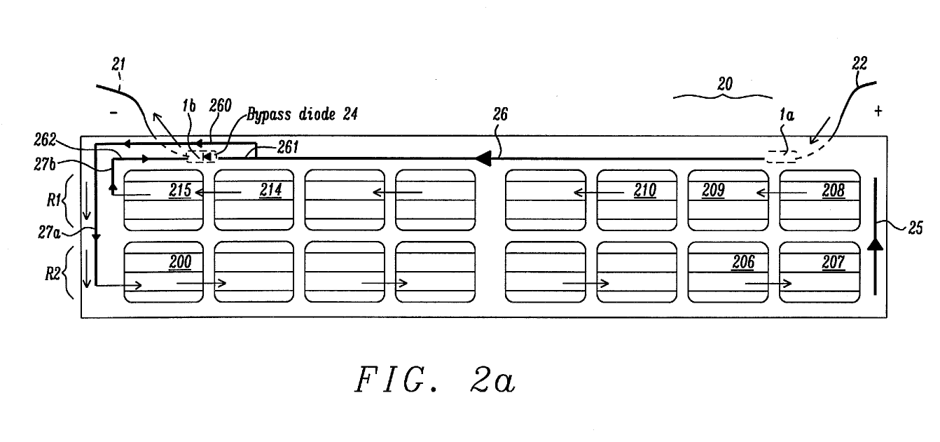

FIG. 1c shows a simplified back view of a roof integrated solar panel circuit design disclosed with a positive junction box 1a and a negative junction box 1b deployed each in a separate corner of the solar panel. A bypass diode 24 is included e.g. in the negative junction box 1b. Furthermore each junction box (J-box) is connected via a short cable to a correspondent connector 2, 3. In a preferred embodiment of the disclosure the length of the cable is about 165 mm, i.e. the distance from the base of the J-box to the base of the connector. The length from base of the J-box to the end of the connector may be may be about 225 mm.

Junction boxes are preferably mounted on the back side of each solar panel. It should be noted that Junction box 1a may be larger than Junction box 1b because J-box 1a houses additionally a bypass diode 24. Furthermore a bypass diode can also be integrated into the solar panel independently of a corner junction box.

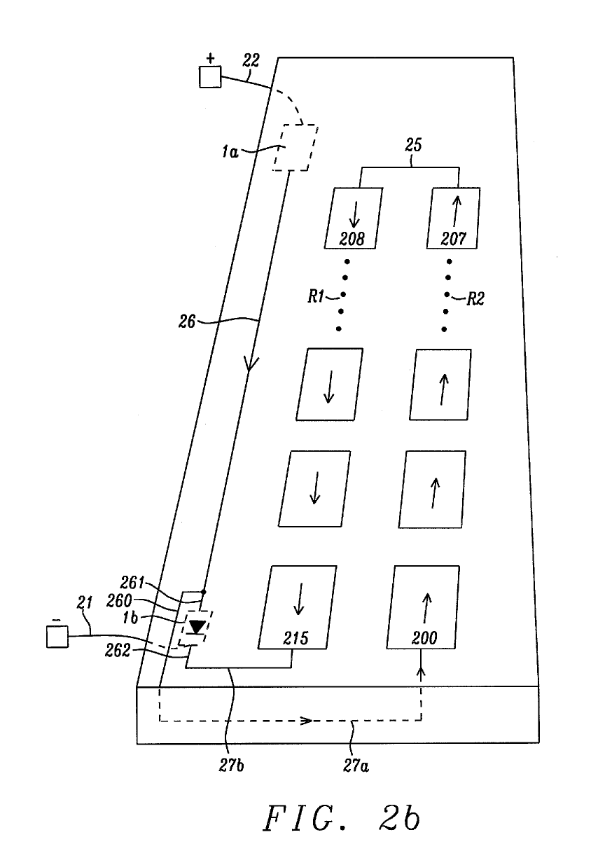

It has to be noted that in the solar panel designs, shown in the following FIGS. 2-7, the right side and the left side features can be interchanged. It is obvious that, if the polarity is changed, the diode must also be reversed to match the polarity change.

FIG. 2a shows a front view of a roof integrated solar panel 20 disclosed with corner J-boxes 1a and 1b mounted on corners of the back side of the solar panel (shown by dashed lines) and with 2 rows R1/R2 of solar cells. The negative terminal of the solar panel is connected via the negative junction box 1b, mounted on back of the solar panel, and short cable 21 to its negative outlet connector (not shown); the positive terminal of the solar panel is connected via the positive junction box 1a, mounted on another corner of the back of the solar panel, and short cable 22 to its outlet connector (not shown).

A long busbar 26 connects the positive junction box 1a in a first branch 260/27a with an utmost solar cell 200 of the second row on the side of the negative outlet 21 of the solar panel. A second branch 261 of the busbar 26 connects the positive J-box 1a with the negative J-box 1b, wherein a bypass diode 24 diverts incoming current past the solar cell circuit in case the cells of a particular solar panel are shaded. The busbar branch 261 is used only during a bypass event, i.e. when via bypass diode 24 incoming current is diverted past the solar cells.

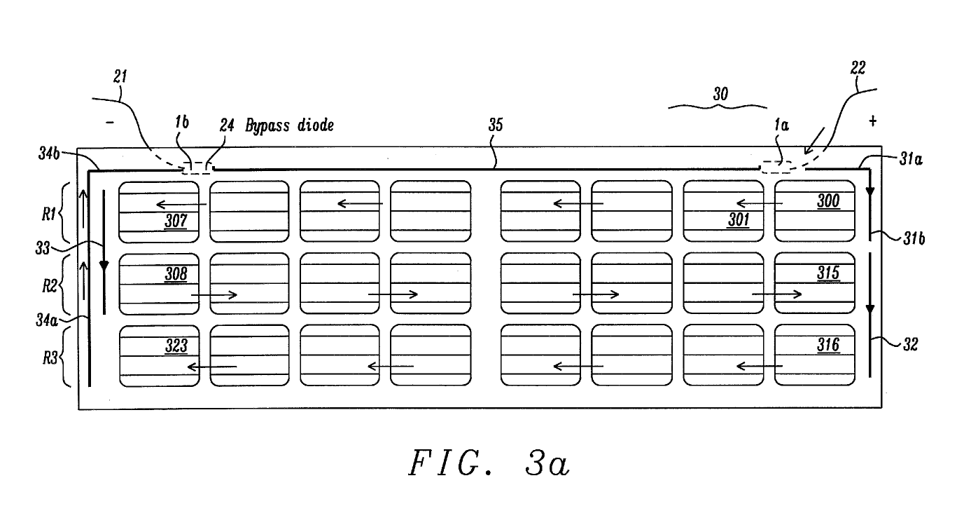

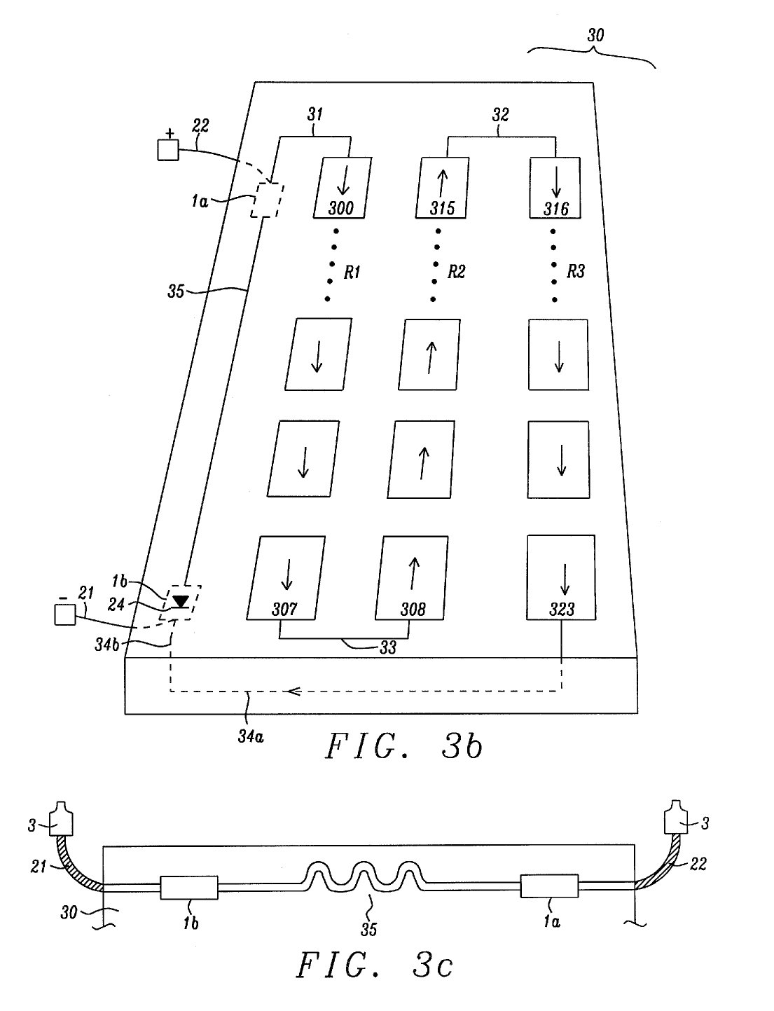

In order to avoid curling of the busbar or strain on the busbar to busbar or busbar to J-box connections at either end of long busbar connection, the design of this busbar must be able to accommodate the thermal expansion and contraction of busbar material, especially during high lamination temperatures. This may be addressed by forming a specialized busbar so that the horizontal expansion is minimized to any particular busbar length and/or joint by e.g. meandering of the busbar. The meandering can be applied to any busbar of the disclosure. This meandering busbar can be soldered together from several different busbars or can be formed from by stamping out of a thin sheet of tinned copper or similar metal. An example of a meandering busbar is shown in FIG. 3c.

The busbar 35 of FIG. 3c connecting both J-boxes 1a and 1b is in the same plane as the cell circuit—i.e. in the middle between two layers of encapsulant (EVA or similar), glass on front and backsheet on back.

A second busbar 25 connects both rows of solar cells on the side of the positive terminal of the solar panel. A third busbar 27b connects a first cell 215 of the first row R1 on the side of the negative outlet of the solar panel with the negative junction box 1b through busbar branch 262. This busbar branch 27b is stacked over the busbar 27a and separated from the busbar 27a by an insulating membrane. Deployment of the busbars 27a and 27b/262 is shown in FIG. 2b. It should be noted that a three-dimensional depiction of the stacking of busbar 27b over busbar 27a is not possible in in FIG. 2a. The purpose of FIG. 2a is to clearly demonstrate the current flow through the busbars.

The arrow tips illustrate the flow of current through the solar panel 20. The current flows from the positive cable 22 port through the positive J-box 1a along busbar 26 via branch 260/27a to solar cell 200 and across solar cells 206, 207, then the current follows the busbar 25 to solar cell 208 and then flows across solar cells 209, 210, ff. to solar cell 215 and then via the busbar 27b/262, the negative J-box 1b to the negative cable outlet 21.

The solar cells 200-215 and accompanying busbars form an electrical circuit which is encapsulated between two substrates to form a solar laminate, which, when mounted onto a plastic frame, makes a solar module, or solar panel.

It should be noted that the solar panel of FIG. 2a is just an example. Solar panels with an even row number may have more than two rows of solar cells. The bus bars of such panels are deployed principally the same way as shown in FIG. 2a for a panel having a 2-row design. The busbars enable a flow of current through all solar cells from the positive J-box to the negative J-box.

FIG. 2b shows a perspective side view of the solar panel having two rows R1-R2. Dashed lines in FIG. 2b indicate features of the solar panel deployed close to the back-side of the solar panel. Busbar 25 connects on the side of the positive outlet the last solar cells 207/208 of rows R2/R1.

It should be noted that busbar 27b262, connecting the utmost cell 215 on the side of the negative terminal 21 of the first row R1 with the negative J-box 1b, is stacked over the busbar 27a, wherein both busbars 27b/262 and 27a are separated by an insulating membrane.

In the example of FIG. 2b the current flows, as indicated by the arrows in the solar cells, through row R2 from solar cell 200 to cell 207, via busbar 25 through row R1 from solar cell 208 to cell 215 and then via busbar 27a/262 to the negative J-box b.

It should be noted that other ways for the current flow would be possible as well. It has to be ensured that the current flow starts at the positive cable connection 22, ends at the negative cable connection 21, and that the current flows through all solar cells in the right direction once.

FIG. 3a shows a front view of a roof integrated solar panel 30 disclosed with corner J-boxes, which are deployed on the back side of the solar panel (illustrated by dashed lines), and with 3 rows, of solar cells. The current flow in the solar panel 30 is similar to the current flow in the solar panel 20 shown in FIGS. 2a/2b but due to the odd number of rows of solar cells some changes have to be made to ensure that the current flow starts at the positive cable 22 connector, ends at the negative cable 21 outlet, and that the current flows as shown by the arrow tips through all solar cells once. The changes affect mostly the deployments of the busbars.

The negative polarity of the solar panel is again connected via a short cable 21, which is connected to the negative J-box 1b at a corner of the backside of the solar panel to its connector (not shown); the positive polarity of the solar panel is connected via a short cable 22 to the positive J-box 1a at a neighboring corner on the back of the solar panel shown by dashed lines.

A first busbar 31a and 31b connects the solar cell 300, located on the top row R1 of solar cells on the side of the positive terminal 22, via the positive J-box 1a to the positive cable connection 22. A second busbar 32 connects on the side of the positive terminal 22 of the solar panel the utmost solar cell 315 on the side of the positive terminal 22 of the middle row R2 of solar cells with the utmost solar cell 316 on the side of the positive terminal 22 of the bottom row R3 of solar cells. A third busbar 33 connects the utmost solar cell 307 of the first row R1 of solar cells on the side of the negative terminal with the utmost solar cell 308 of the middle row of solar cells on the side of the negative terminal, wherein a fourth busbar 34a is stacked under the third busbar 33 separated by an insulating membrane from the third busbar 33.

This fourth busbar 34 connects the utmost solar cell 323 on the side of the negative terminal of the bottom row of solar cells with the negative Jbox 1b. The long busbar 35 is used only during a bypass event, i.e. when via bypass diode 24 incoming current is diverted past the solar cells, usually due to shading of one or more solar cells in that particular solar panel. In'order to avoid curling of the busbar or strain on the busbar to J-box connections at either end of long busbar connection 35, the design of this busbar must be able to accommodate the thermal expansion of busbar material, especially during high temperature lamination. This may be addressed by forming a meandering busbar so that the horizontal expansion is minimized to any particular busbar length and/or joint, i.e. the meandering can be applied to any busbar of the disclosure. This meandering busbar can be soldered together from several different busbars or can be formed from by stamping out of a thin sheet of tinned copper or similar metal.

An example of the meandering busbar 35 is shown in FIG. 3c. In this example the busbar 35 has a shape like a “snake”. Furthermore FIG. 3c shows the cables 21/22, the two connectors 3, and both junction boxes 1a/1b, deployed each in opposite corners on a same side of the solar panel 30. The cables may have a length of about 165 mm. It should be noted that the example of the meandering busbar of FIG. 3c is also applicable to the long busbar 26 shown in FIGS. 2a and 2b. Furthermore it should be noted that FIG. 3c shows a non-limiting example of a specialized busbar. Other specialized busbar designs are possible as well as e.g. varying the number and shapes of the bends.

The arrow tips illustrate the flow of current through the solar panel 30. The current flows from cable 22 through the positive J-box 1a along busbar 31a and 31b to solar cell 300 and across solar cells 300, 301 ff. to solar cell 307, then the current follows the busbar 33 to solar cell 308 and then flows across solar cells 308, 309 ff. to solar cell 315 and then via the busbar 32 to the solar cell 316 and across solar cells 316, 317 ff. to solar cell 323 and from there via the busbar 34a and 34b and via the negative J-box 1b to the negative cable outlet 21.

FIG. 3b shows a perspective side view of a solar panel having an odd number of rows, namely 3 rows in the case of FIG. 3b. Busbar 33 connects on the side of the negative outlet the first solar cell 307 of the first row R1 with the first solar cell 308 of the second row R2. The busbar 34 is stacked under the busbar 33 separated by an insulating membrane from the busbar 34a. The busbars 34a and 34b connect the first cell 323 of the bottom R3 row with the negative Jbox 1b.

Furthermore it should be noted that solar panels having one row of solar panels can be built following the same principles as, outlined above in regard of solar panels having two or three rows, i.e. these solar panels have also J-boxes deployed on opposite corners on a same side of the solar panel, have short cables as the other solar panels disclosed and can be connected to other solar panels the same way.

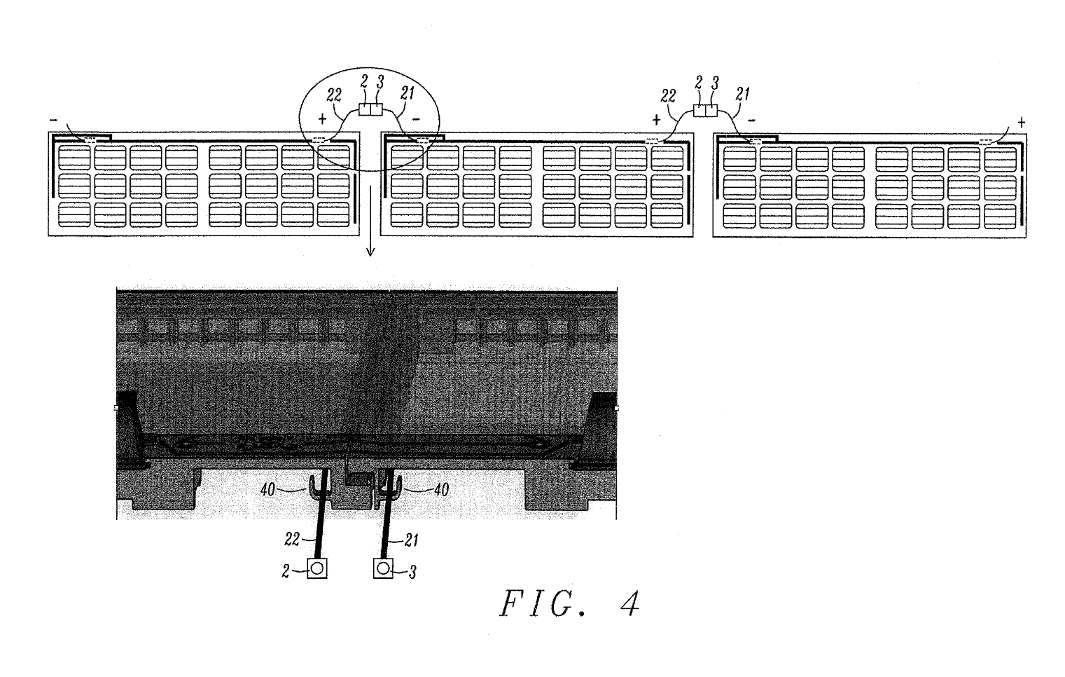

FIG. 4 illustrates simple panel-to-panel connection of solar panels without cable management required. This kind of connections are made possible by deploying the junction boxes in the corner of the solar panels as disclosed in FIGS. 1-3 and by the wiring layout as disclosed in FIGS. 2-3. The panel-to-panel connections within a row of solar panels disclosed are achieved in two steps. First the cables are laid into the integrated hooks and then the panels are laid down and attached to the roof deck or battens. The integrated hooks keep cables and connectors at either end of the solar panels from potentially getting pinched between the solar panel and roof decking or battens during installation. Second once the panel is securely fastened to the roof deck or battens, the positive or negative connector of one panel is taken out of the hooks and connected to the neighboring positive or negative connector of the adjacent panel. Because the cables are short, there is no additional cable management required to ensure the cables stay off the roof deck and are not pinched during subsequent installation steps. The integrated hooks shown in FIG. 4 and the panel design shown in FIGS. 1-3 together facilitate a simple module to module connection to be made without any requirement for additional cable management.

On top of FIG. 4 are three solar panels which have positive and negative connectors 3/2 deployed side-by side and they can be connected without any cable management required. Once the solar panels are fastened to roof deck the positive and negative connectors avoid any cable management problems.

On the bottom of FIG. 4 a back view of top of solar panels is shown. Hooks 40 integrated into the frame hold the short cables with connectors at the end and keep the cables from getting pinched when the panels are laid down and secured to the roof deck or to battens. Furthermore the cables 22 and 23 and the related connectors 2 and 3 are shown. The short cables 22/23 are kept in the hooks 40 until the connectors are ready to be plugged together

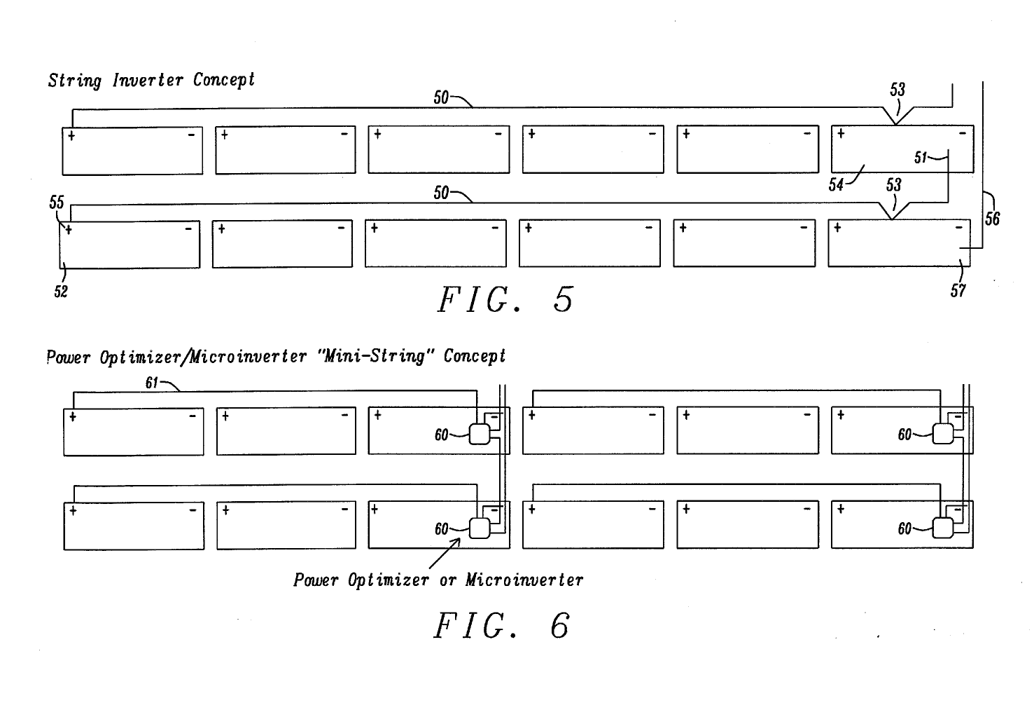

FIG. 5 shows a simple row-to-row connection of solar panels, which can be used to connect multiple rows of roof-integrated solar panels and thereby form a string of solar panels, one or more of which form an array following a string inverter concept disclosed. Prerequisite are to have J-Boxes installed in the corners of the solar panels and simple end-to-end connections as e.g. shown in FIG. 4. A solar panel string is thus formed from one or more rows of solar panels connected by a jumper cable and an additional home run cable which is connects the first solar panel in the string to the string inverter. Furthermore FIG. 5 shows a “home run” cable 56, which is the initial cable connecting into the first panel of the 57 solar array. The solar panels of FIG. 5 are implemented in landscape orientation enabling short end to short end connections.

Furthermore the string inverter concept is characterized by using jumper cable 50 to run from a positive terminal 55 of an utmost front end cell 52 of a row via a mechanical cable tie-down 53 deployed at the same row to a negative terminal 51 of an utmost back end cell 54 of the next row. The tie-down 53 is a mechanical, not electrical cable connection. A jumper cable would be laid down in plain sight before the next panels are installed with an overlap that will cover the jumper and the top part of the panels in the row below. The jumper cable can be tied to the hook 40 of a same-row panel before it is bent and laid down over the next row batten or area of roof deck which will receive the first panel of the next row. As the first panel of the next row is being laid down, the installer can take the back end of the jumper cable and insert it into the hook 40 so that the jumper cable is also not pinched between the roof deck and or battens and the solar panel which is being installed.

It is important to note that by using the jumper cable there is no need to twist or stow excess cable.

FIG. 6 illustrates a power optimizer/microinverter “mini-string” concept.

A power optimizer is a DC to DC conversion technology developed to maximize the energy harvest from solar photovoltaic panels or arrays. They do this by individually tuning the performance of each panel or set of panels through maximum power point tracking (MPPT), and delivering a set voltage from the panel or group of panels to the inverter. Power optimizers are wired together in parallel, so even the failure of one of the panels or power optimizers will not lead to a loss of power from the string.

Microinverters convert solar panel DC power directly to AC power for a specific panel or set of panels. This allows the microinverter to provide MPPT for each panel or group of panels and directly output AC power that matches the grid to a grid interconnection point. Microinverters are wired together in parallel, so even the failure of one of the panels or micro inverters will not lead to a loss of power from the string.

FIG. 6 shows a deployment of two power optimizers 60 in a row. It should be noted that also one or more power optimizers may be deployed in one row. A power optimizer “mini-string” may have only as many solar panels in series as can be accommodated by the rated power, voltage and current of the power optimizer, but may have as few as only one solar panels also. Power optimizers 60 may make an installation of solar panels more shade tolerant and make it easier to fit any number of panels onto a roof or multiple roof planes without compromising performance. A jumper cable 61 connects a group of roof-integrated solar panels into a power optimizer 60 to form a “mini-string”. Individual “mini-strings” or power optimizers are then connected together in parallel and connected to an inverter for a solar array.

A roof-integrated solar panel ‘mini-string” can also be formed with a microinverter 60 in a similar manner to that of a power optimizer, with the main difference being that the solar panel's DC power is converted to AC by the microinverter and that the string of microinverters are then connected directly to a grid interconnection point. Furthermore FIG. 6 shows that the power optimizer or microinverters can also provide row-to-row or group-to-group connections.

The jumper cable and power optimizer or microinverter can be attached to the roof deck in plain sight prior to the next row's mini-string being laid down. The use of one or more jumper cables per “mini-string” enables the solar panels of each “mini-string” to be arranged in a variety of shapes.

The elements 60 shown in FIG. 6 can be either optimizers or microinverters. The mini-strings 60 can be installed either in parallel or in serial fashion.

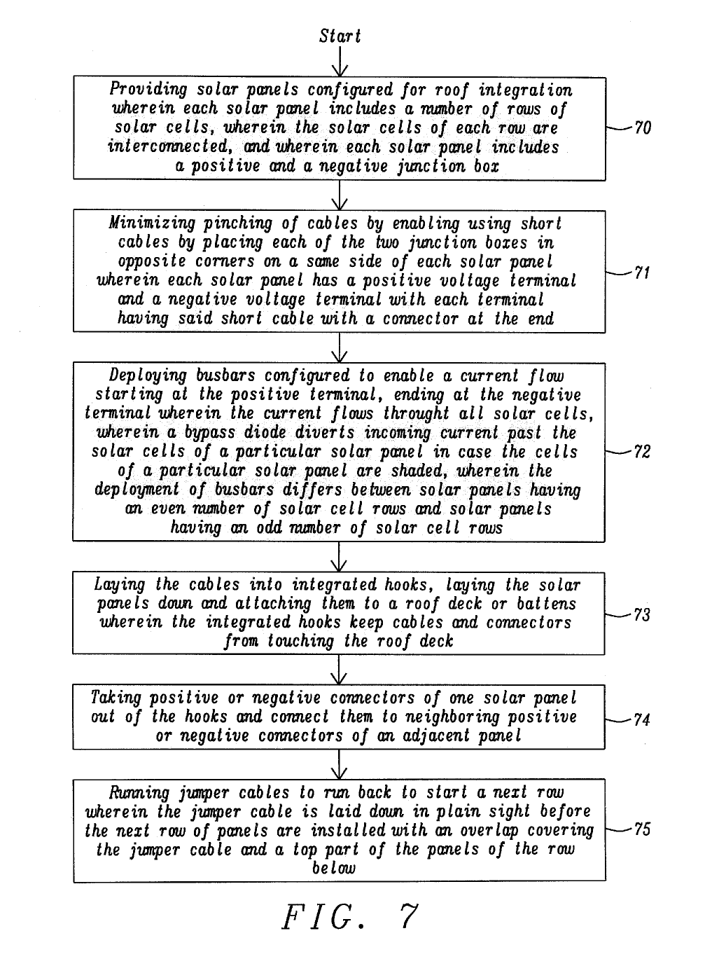

FIG. 7 shows a flowchart of a method to achieve roof-integrated solar panels with short cables and connectors at opposite ends.

A first step 70 shows providing solar panels configured for roof integration, wherein each solar panel comprises a number of rows of solar cells, wherein the solar cells of each row are interconnected, and wherein each solar panel includes a positive and a negative junction box. The following step 71 describes minimizing pinching of cables by enabling using short cables by placing each of the two junction boxes in opposite corners on the same side of each solar panel wherein each solar panel has a positive voltage terminal and a negative voltage terminal with each terminal having said short cable with a connector at the end. Step 72 illustrates deploying busbars configured to enable a current flow starting at the positive terminal, ending at the negative terminal wherein the current flows through all solar cells, wherein a bypass diode diverts incoming current past the solar cells of a particular solar panel in case the cells of a particular solar panel are shaded, wherein the deployment of busbars differs between solar panels having an even number of solar cell rows and solar panels having an odd number of solar cell rows. Step 73 depicts laying the cables into integrated hooks, laying the solar panels down and attaching them to a roof deck or battens wherein the integrated hooks keep cables and connectors from touching the roof deck. Step 74 shows taking positive or negative connectors of one solar panel out of the hooks and connect them to neighboring positive or negative connectors of an adjacent panel. Step 75 teaches running jumper cables to run back to start a next row wherein the jumper cable is laid down in plain sight before the next row panels are installed with an overlap covering the jumper cable and a top part of the panels of the row below.

Thus the jumper cable can be tied to the hook of a same-row panel before it is bent and laid down over the next row batten or area of roof deck which will receive the first panel of the next row and as a first panel of the next row is being laid down, the installer can take the end of the jumper cable and insert it into the hook so that the jumper cable is also not pinched between the roof deck and or battens and the solar panel which is being installed and thus there is no need to twist or stow away excess cable.

While the invention has been particularly shown and described with reference to the preferred embodiments thereof, it will be understood by those skilled in the art that various changes in form and details may be made without departing from the spirit and scope of the invention.

What is claimed is:

1. A solar panel capable of roof integration with short cables and connectors at opposite ends, comprising:
a number of solar cells deployed in one or more rows, wherein the solar cells of each row are interconnected;
a positive and a negative junction box located each in an opposite corner on the same side of the solar panel wherein each solar panel has a positive voltage terminal and a negative voltage terminal with short cables and connectors on the same side, wherein a positive junction box is connected to the positive voltage terminal and the negative junction box is connected to the negative voltage terminal;
a bypass diode; and
a number of busbars located at top and at both sides of the solar panel configured to enable a current flow starting at the positive terminal, ending at the negative terminal wherein the current flows through all solar cells unless the bypass diode diverts incoming current past the solar cells due to shading of a particular solar panel, wherein the deployment of busbars differs between solar panels having an even number of rows of solar cells and solar panels having an odd number of rows of solar cells.

2. The solar panel of claim 1, wherein both junction boxes and the positive voltage terminal and the negative voltage terminal with short cables and connectors are placed on the back side of the solar panel.

3. The solar panel of claim 1, wherein the solar panel has two rows of solar cells and wherein the positive terminal connection via the junction box is located in a corner on a first side of the solar panel, a first busbar connects by a first branch of the first busbar the junction box on the first side with an utmost cell of a second row on the second side of the solar panel, wherein a second branch of the first busbar interconnects both junction boxes, a second busbar connects on the first side of the solar panel the first row with a second row of solar cells, a third busbar connects an utmost cell of the first row on the second side of the solar panel with the negative junction box connected with the negative terminal on the second side, wherein the busbar connected to the first cell of the second row with the negative junction box is stacked under the third busbar, wherein both busbars are separated by an insulating membrane.

4. The solar panel of claim 3, capable of allowing the flow of current through the solar panel starting at the positive terminal connection along the first branch of the first busbar to the utmost solar cell of the second row of solar cells on the second side of the solar panel and across the second row of solar cells from the second side to the first side, then the current flows through the second busbar to the utmost solar cell on the first side of the first row of solar cells and then across the solar cells of the first row from the first side to the second side and then the current flows via the third busbar and via the negative junction box to the negative cable outlet.

5. The solar panel of claim 3, wherein the features on the first side of the solar panel are interchanged with the features on the left side of the solar panel.

6. The solar panel of claim 5, wherein the first side of the solar panel is the right side of the solar panel.

7. The solar panel of claim 1, wherein the solar panel has three rows of solar cells and wherein the positive terminal connection is located in a corner of a first side of the solar panel, a first busbar connects the junction box of the positive polarity connection side with an utmost solar cell on the first side of a first row of solar cells, a second busbar connects on the first side of the solar panel an utmost cell of a middle row of solar cells with an utmost solar cell of third row of solar cells, a third busbar connects the junction box of the first side with the junction box of the second side, wherein the third busbar is used only during when a bypass diode diverts incoming current past the solar cells in case the solar cells cannot generate a current, a fourth busbar connects on the second side an utmost first solar cell of the first row with an utmost solar cell of the second row of solar cells, and a fifth busbar connects on the second side an utmost cell of the third row with the junction box of second side, wherein the fifth busbar is stacked under the fourth busbar and is separated from these busbars by an insulating membrane.

8. The solar panel of claim 7, capable of allowing the flow of current through the solar panel starts at the positive cable connection through the junction box of the first side along the first busbar to the first solar cell located on an utmost first side of the first row of solar cells and across the solar cells of the first row from the first to the second side, then the current follows the fourth busbar on the second side of the solar panel to the middle row, flows then across the solar cells of the middle row from the second side to an utmost solar cell of the first side, then the current flows from via the second busbar along the third row from the first side to the second side, and then the current flows through the fifth busbar via the negative junction box on the second side to the negative cable outlet.

9. The solar panel of claim 7, wherein the features on the first side of the solar panel are interchanged with the features on the second side of the solar panel.

10. The solar panel of claim 1, wherein the solar panel has one row of solar cells and wherein the positive terminal connection is located in a corner of a first side of the solar panel, a first busbar connects the junction box of the positive polarity connection side with an utmost solar cell on the first side of the row of solar cells and a second busbar connects on a second side of the solar panel an utmost cell of the row of solar cells with the junction box of the negative polarity.

11. The solar panel of claim 1, wherein said short cables may have a length of about 165 mm without connector.

12. The solar panel of claim 1, wherein one or more meandering busbars are used to provide flexibility to allow for thermal expansion and contraction of the busbar.

13. The solar panel of claim 12, wherein said meandering busbars have two or more bends.

14. The solar panel of claim 1, wherein the bypass diode is included in the negative junction box.

15. The solar panel of claim 1, wherein the bypass diode is integrated in the solar panel separately from a junction box included in the negative junction box.

16. A solar panel array capable of roof integration of a number of solar panels with short cables and connectors and junction boxes at opposite ends at the same side, comprising:
a number of solar panels each solar panel comprising:
a number of solar cells deployed in one or more rows;
a positive and a negative junction box located each in an opposite corner on the same side of each solar panel, wherein each solar panel has a positive voltage terminal and a negative voltage terminal with short cables and connectors at the opposite corners on the same side, wherein a positive junction box is connected to the positive voltage terminal and the negative junction box is connected to the negative voltage terminal;
a bypass diode; and
a number of busbars located at top and at both sides of each solar panel enabling a current flow starting at the positive terminal, ending at the negative terminal, wherein the current flows through all solar cells unless said bypass diode diverts incoming current past the solar cells due to shading of a particular solar panel, wherein the deployment of busbars differs between solar panels having an even number of rows of solar cells and solar panels having an odd number of rows of solar cells;
wherein the connectors at each end of the short cables provide directly connection from one solar panel to a neighboring solar panel to form a row of solar panels.

17. The solar panel array of claim 16, wherein a jumper cable provides connections from a row of solar panels to a next row of solar panels to form the solar array from one or more strings of solar panels.

18. The solar panel of claim 17, wherein said jumper cable runs from a positive terminal of an utmost front end cell of a row via a mechanical cable tie-down connection, deployed at the same row, to a negative terminal of an utmost back end cell of the next row.

19. The solar panel array of claim 16, wherein a jumper cable may connect a group of roof-integrated solar panels into a DC-to-DC power optimizer or DC-to-AC microinverters, wherein other groups of roof-integrated solar panels connected to other DC to DC power optimizers or DC-to-AC microinverters can be joined together to form the solar array.

20. The solar panel array of claim 19, wherein the jumper cable connects a group of roof-integrated solar panels into a power optimizer to form a mini-string of solar panels, wherein individual mini-strings or power optimizers are then connected together in parallel and connected to an inverter forming the solar array.

21. The solar panel array of claim 16, wherein a string of microinverters is connected directly to a grid interconnection point.

22. The solar panel array of claim 16, wherein said short cables may have a length of about 165 mm.

23. The solar panel array of claim 16, wherein one or more meandering busbars are used to provide flexibility to absorb the thermal expansion and contraction of the busbar.

24. The solar panel array of claim 23, wherein said meandering busbars have two or more bends.

25. The solar panel array of claim 16, wherein panel-to-panel connections within a row of solar panels are achieved using integrated hooks configured to keeping cables and connectors at either end of the solar panels from touching the roof's decking or panels during installation.

26. The solar panel array of claim 16, wherein the solar panels are in landscape orientation enabling short end to short end connections.

27. The solar panel array of claim 16, wherein the solar panels are in portrait orientation.

28. A method to achieve roof-integrated solar panels with two junctions boxes, short cables and connectors at opposite corners of a same side, the method comprising the steps of:
(1) providing solar panels configured for roof integration, wherein each solar panel comprises one or more rows of solar cells, wherein the solar cells of each row are interconnected, and wherein each solar panel includes a positive and a negative junction box;
(2) minimizing pinching of cables by enabling using short cables by placing each of the two junction boxes in opposite corners on the same side of each solar panel wherein each solar panel has a positive voltage terminal and a negative voltage terminal connected to the correspondent positive or negative junction box with each terminal having said short cable with a connector at the end;
(3) deploying busbars configured to enable a current flow starting at the positive terminal outlet, ending at the negative terminal outlet, wherein the current flows through all solar cells, wherein a bypass diode diverts incoming current past the solar cells of a particular solar panel in case the cells of the particular solar panel are shaded, wherein the deployment of busbars differs between solar panels having an even number of solar cell rows and solar panels having an odd number of solar cells rows;
(4) laying the cables into integrated hooks, laying the solar panels down and attaching them to a roof deck or battens wherein the integrated hooks keep cables from getting pinched between the solar panel and roof deck or battens during installation; and
(5) taking positive or negative connectors of one solar panel out of the hooks and connect them to neighboring positive or negative connectors of an adjacent panel.

29. The method of claim 28 wherein the solar panels are installed in landscape orientation enabling short end to short end connections.

30. The method of claim 28, wherein the solar panels are installed in portrait orientation.

31. The method of claim 28, wherein the solar panel has two rows of solar cells and wherein the positive terminal connection via the junction box is located in a corner on a first side of the solar panel, a first busbar connects by a first branch of the first busbar the junction box on the first side with an utmost cell of a first row on the second side of the solar panel, wherein a second branch of the first busbar interconnects both junction boxes, a second busbar connects on the first side of the solar panel the first row with a second row of solar cells, a third busbar connects an utmost cell of the second row on the second side of the solar panel with the negative junction box connected with the negative terminal on the second side, wherein the busbar connected to the first cell of the second row with the negative junction box is stacked under the first branch of the first busbar, wherein both busbars are separated by an insulating membrane.

32. The method of claim 31, wherein the flow of current through the solar panel starts at the positive terminal connection along the first branch of the first busbar to the utmost solar cell of the first row of solar cells on the second side of the solar panel and across the first row of solar cells from the second side to the first side, then the current flows through the second busbar to the utmost solar cell on the first side of the second row of solar cells and then across the solar cells of the next row from the first side to the second side and then the current flows via the third busbar and via the negative junction box to the negative cable outlet.

33. The method of claim 31, wherein the features on the first side of the solar panel are interchanged with the features of the second side of the solar panel.

34. The method of claim 31, wherein the solar panel has an even number of rows, which is higher than two and wherein the busbars are deployed correspondently to the deployment of busbars of the solar panel having two rows of solar cells.

35. The method of claim 28, wherein the solar panel has three rows of solar cells and wherein the positive terminal connection is located in a corner of a first side of the solar panel, a first busbar connects the junction box of the positive polarity connection side with an utmost solar cell on the first side of a first row of solar cells, a second busbar connects on the first side of the solar panel an utmost cell of a middle row of solar cells with an utmost solar cell of third row of solar cells, a third busbar connects the junction box of the first side with the junction box of the second side, wherein the third busbar is used only during when a bypass diode diverts incoming current past the solar cells in case the solar cells cannot generate a current, a fourth busbar connects on the second side an utmost first solar cell of the first row with an utmost solar cell of the second row of solar cells, and a fifth busbar connects on the second side an utmost cell of the third row with the junction box of second side, wherein the fifth busbar is stacked under the fourth busbar and is separated from these busbars by an insulating membrane.

36. The method of claim 35, wherein the flow of current through the solar panel starts at the positive cable connection through the junction box of the first side along the first busbar to the first solar cell located on an utmost first side of the first row of solar cells and across the solar cells of the first row from the first to the second side, then the current follows the fourth busbar on the second side of the solar panel to the middle row, flows then across the solar cells of the middle row from the second side to an utmost solar cell of the first side, then the current flows from via the second busbar along the third row from the first side to the second side, and then the current flows through the fifth busbar via the negative junction box on the second side to the negative cable outlet.

37. The method of claim 35, wherein the features on the first side of the solar panel are interchanged with the features on the second side of the solar panel.

38. The method of claim 35, wherein the solar panel has an odd number of rows, which is higher than three and wherein the busbars are deployed correspondently to the deployment of busbars of the solar panel having three rows of solar cells.

39. The method of claim 28, wherein panel-to-panel connections within a row of solar panels are achieved using integrated hooks configured to keeping cables and connectors at either end of the solar panels from getting pinched between the solar panel and the rood deck or battens during installation.

40. The method of claim 28 wherein row-to-row panel connections are achieved using jumper cables, wherein the jumper cables connect a last roof-integrated solar panel in a row to the next or first solar panel in the next row, wherein the jumper cable is be laid down in plain sight and is capable to be secured to a roof decking before the first panel in the new row is installed wherein a threat of pinching the cables by the installation of the next or overlapping row's panels is also reduced by enabling successive rows to interlock above the roof deck, leaving space for the jumper cable to lie unhindered and protected by the overlapping panel.

41. The method of claim 40, wherein the jumper cable can be tied to the hook of a same-row panel before it is bent and laid down over the next row batten or area of roof deck which will receive the first panel of the next row and as a first panel of the next row is being laid down, the installer can take the end of the jumper cable and insert it into the hook so that the jumper cable is also not pinched between the roof deck and or battens and the solar panel which is being installed and thus there is no need to twist or stow away excess cable.

42. The method of claim 28, wherein a jumper cable may connect a group of roof-integrated solar panels into a group of DC-to-DC power optimized solar panels or may connect a group of solar panels having their power converted from DC to AC converted by micro inverters, wherein the power optimizer or microinverters provide also row-to-row interconnections directly to neighboring solar panels of rows above or below a present row of solar panels.

43. The method of claim 28, wherein said short cables may have a length of about 165 mm.

44. The method of claim 28, wherein one or more meandering busbars are used to provide flexibility to absorb the thermal expansion and contraction of the busbar.

45. The method of claim 44, wherein said meandering busbars have two or more bends.
